(19) United States
(12) Patent Application Publication
(10) Pub. No.: US 2022/0238788 A1
(43) Pub. Date: Jul. 28, 2022

(54) ROBOT AND END EFFECTOR

(71) Applicant: SEIKO EPSON CORPORATION, Tokyo (JP)

(72) Inventor: Tomohisa IWAZAKI, SUWA-GUN SHIMOSUWA-MACHI (JP)

(21) Appl. No.: 17/580,672

(22) Filed: Jan. 21, 2022

(30) Foreign Application Priority Data
Jan. 25, 2021 (JP) 2021-009360

(51) Int. Cl. H01L 41/09; B25J 15/02

(52) U.S. Cl. CPC H01L 41/09; B25J 9/126; B25J 15/0253

(57) ABSTRACT

A robot including a manipulator having a plurality of joints and a base supporting the manipulator, includes a first piezoelectric motor and a second piezoelectric motor respectively having vibrators that transmit drive forces to a driven portion and performing rotary driving, wherein a distance between a rotation axis and the vibrator is smaller in the second piezoelectric motor than in the first piezoelectric motor, a plurality of the vibrators are placed along rotation axis directions in the second piezoelectric motor, and the second piezoelectric motor is placed closer to a distal end side opposite to the base than the first piezoelectric motor.

The present application is based on, and claims priority from JP Application Serial Number 2021-009360, filed Jan. 25, 2021, the disclosure of which is hereby incorporated by reference herein in its entirety.

### BACKGROUND

### 1. Technical Field

The present disclosure relates to a robot and an end effector.

### 2. Related Art

For example, a robot disclosed in JP-A-2015-71214 includes an end effector having a gripping function at the distal end of a robot arm and uses an ultrasonic motor as a rotary drive source. When work of feeding, removing, transport, assembly, etc. of precision apparatuses and components forming the apparatuses is performed, downsizing of the end effector and the robot arm is required with downsizing of the precision apparatuses and the components forming the apparatuses.

However, in the robot disclosed in JP-A-2015-71214, there is a problem that downsizing of the end effector and the robot arm is difficult in view of the structure.

### SUMMARY

A robot including a manipulator having a plurality of joints and a base supporting the manipulator, includes a first piezoelectric motor and a second piezoelectric motor respectively having vibrators that transmit drive forces to a driven portion and performing rotary driving, wherein a distance between a rotation axis and the vibrator is smaller in the second piezoelectric motor than in the first piezoelectric motor, a plurality of the vibrators are placed along rotation axis directions in the second piezoelectric motor, and the second piezoelectric motor is placed closer to a distal end side opposite to the base than the first piezoelectric motor.

An end effector is attached to a distal end of a manipulator, and includes a first piezoelectric motor and a second piezoelectric motor respectively having vibrators that transmit drive forces to a driven portion and performing rotary driving, wherein a distance between a rotation axis and the vibrator is smaller in the second piezoelectric motor than in the first piezoelectric motor, a plurality of the vibrators are placed along rotation axis directions in the second piezoelectric motor, and the second piezoelectric motor is placed closer to a distal end side opposite to the manipulator than the first piezoelectric motor.

### BRIEF DESCRIPTION OF THE DRAWINGS

FIG. 1 is a perspective view showing a robot according to a first embodiment.

FIG. 2 is a plan view showing an end effector of the robot.

FIG. 3 is a sectional view showing a first piezoelectric motor of the end effector in FIG. 2.

FIG. 4 is a plan view showing a vibrator of the first piezoelectric motor in FIG. 3.

FIG. 5 is a sectional view showing a second piezoelectric motor of the end effector in FIG. 2.

FIG. 6 a sectional view showing a second piezoelectric motor of a robot according to a second embodiment.

### DESCRIPTION OF EXEMPLARY EMBODIMENTS

### 1. First Embodiment

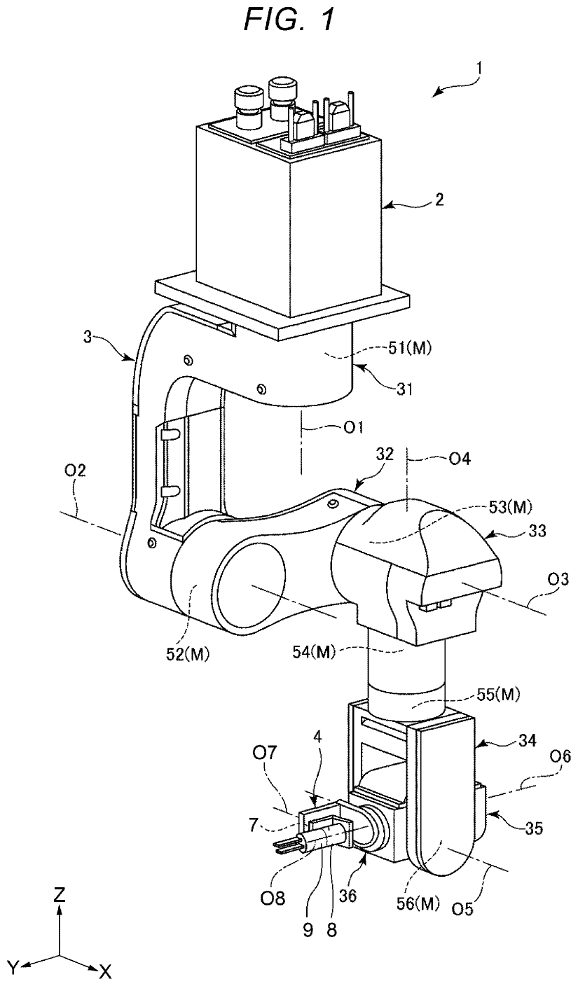

First, a robot 1 according to a first embodiment will be explained with reference to FIGS. 1 to 5.

For convenience of explanation, in the following drawings, an X-axis, a Y-axis, and a Z-axis are shown as three axes orthogonal to one another. Further, directions along the X-axis are referred to as “X directions”, directions along the Y-axis are referred to as “Y directions”, and directions along the Z-axis are referred to as “Z directions”. Furthermore, the arrow-head sides of the individual axes are also referred to as “plus sides”, and the opposite sides to the arrow-heads are also referred to as “minus sides”.

The robot 1 shown in FIG. 1 may perform work of e.g. feeding, removing, transport, assembly, etc. of precision apparatuses and components forming the apparatuses. The application of the robot 1 is not limited to that. The robot 1 is a vertical articulated robot having a plurality of joints and includes a base 2 and a manipulator 3. The manipulator 3 has a first arm 31, a second arm 32, a third arm 33, a fourth arm 34, a fifth arm 35, a sixth arm 36, and an end effector 4. In the following explanation, the base 2 side of the manipulator 3 is also referred to as “proximal end” or “proximal end side” and the opposite side to the base 2, i.e., a side away from the base 2 is also referred to as “distal end” or “distal end side”.

The base 2 is fixed to a floor, a wall, a ceiling, or the like. The first arm 31 is coupled to the base 2 pivotably around a first arm pivot axis O1 at the proximal end side of the first arm. The second arm 32 is coupled to the first arm 31 pivotably around a second arm pivot axis O2 orthogonal to the first arm pivot axis O1 at the proximal end side of the second arm. The third arm 33 is coupled to the second arm 32 pivotably around a third arm pivot axis O3 parallel to the second arm pivot axis O2 at the proximal end side of the third arm. The fourth arm 34 is coupled to the third arm 33 pivotably around a fourth arm pivot axis O4 orthogonal to the third arm pivot axis O3 at the proximal end side of the fourth arm. The fifth arm 35 is coupled to the fourth arm 34 pivotably around a fifth arm pivot axis O5 orthogonal to the fourth arm pivot axis O4 at the proximal end side of the fifth arm. The sixth arm 36 is coupled to the fifth arm 35 pivotably around a sixth arm pivot axis O6 orthogonal to the fifth arm pivot axis O5 at the proximal end side of the sixth arm. The end effector 4 is detachably attached to the distal end side of the sixth arm 36.

Note that, regarding the first arm pivot axis O1 to sixth arm pivot axis O6 and a first axis O7 and a second axis O8, which will be described later, “orthogonal” includes a case where an angle between two axes is different within a range of ±5° from 90°, and “parallel” includes a case where one of two axes is inclined within a range of ±5° relative to the other.

The robot 1 has a first arm drive unit 51 provided in the coupling portion between the base 2 and the first arm 31 and pivoting the first arm 31 relative to the base 2, a second arm drive unit 52 provided in the coupling portion between the first arm 31 and the second arm 32 and pivoting the second arm 32 relative to the first arm 31, a third arm drive unit 53 provided in the coupling portion between the second arm 32 and the third arm 33 and pivoting the third arm 33 relative to the second arm 32, a fourth arm drive unit 54 provided in the coupling portion between the third arm 33 and the fourth arm 34 and pivoting the fourth arm 34 relative to the third arm 33, a fifth arm drive unit 55 provided in the coupling portion between the fourth arm 34 and the fifth arm 35 and pivoting the fifth arm 35 relative to the fourth arm 34, and a sixth arm drive unit 56 provided in the coupling portion between the fifth arm 35 and the sixth arm 36 and pivoting the sixth arm 36 relative to the fifth arm 35. The individual arm drive units 51 to 56 correspond to the joints of the robot 1.

Each of the first arm drive unit 51 to sixth arm drive unit 56 includes e.g. a motor M as a drive source of the arm, a controller that controls driving of the motor M, a reducer, an encoder, etc. The motor M is not particularly limited, but a piezoelectric motor using expansion and contraction of a piezoelectric element by energization is preferably used. Thereby, for example, compared to a case where an electromagnetic motor or the like is used as the motor M, downsizing of the motor M may be realized. Further, for example, the piezoelectric motor has an advantage in driving at a lower speed and lower torque over an electromagnetic motor and is suitable for driving of the robot 1 because of the advantage. The configuration of the piezoelectric motor is not particularly limited, but may be e.g. the same configuration as a first piezoelectric motor 7 and a second piezoelectric motor 8, which will be described later.

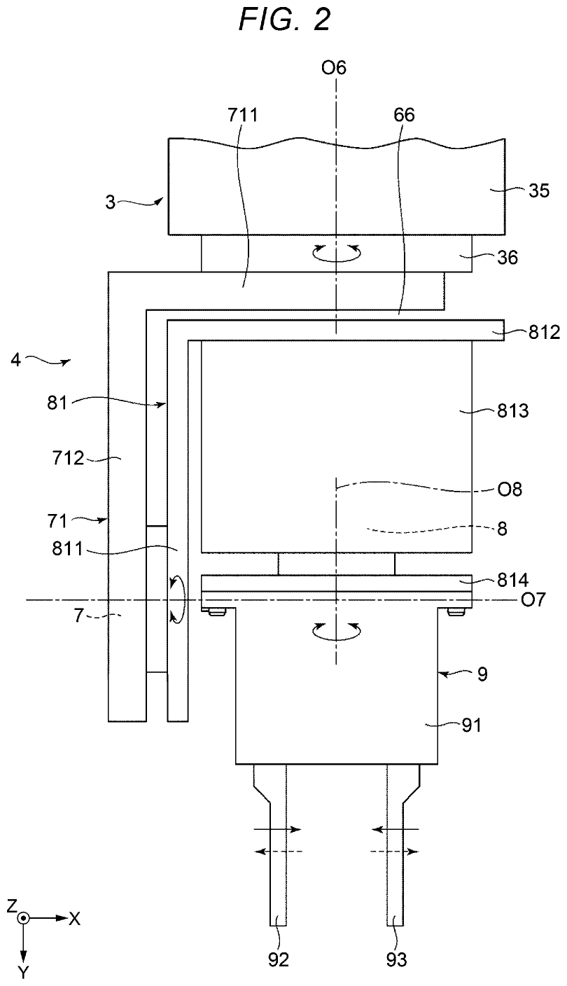

As shown in FIG. 2, the end effector 4 has a gripping unit 9 that grips a workpiece, a first holding unit 71 that holds the first piezoelectric motor 7 pivoting the gripping unit 9 around the first axis O7, and a second holding unit 81 that holds the second piezoelectric motor 8 pivoting the gripping unit 9 around the second axis O8 orthogonal to the first axis O7. The second piezoelectric motor 8 is placed closer to the distal end side opposite to the manipulator 3 than the first piezoelectric motor 7.

The end effector 4 is attached to the distal end side of the sixth arm 36 via the first holding unit 71 having the first piezoelectric motor 7.

The first holding unit 71 has an L-shape bending at a right angle in the middle, and has a first coupling portion 711 coupling to the distal end side of the sixth arm 36 and a second coupling portion 712 holding the first piezoelectric motor 7 and coupling to the second holding unit 81 having the second piezoelectric motor 8. Further, the first coupling portion 711 extends in directions orthogonal to the sixth arm pivot axis O6 of the sixth arm 36 and couples to the second coupling portion 712, and the second coupling portion 712 extends along the sixth arm pivot axis O6 of the sixth arm 36 from the coupling part to the first coupling portion 711.

The second holding unit 81 has a first coupling portion 811 coupling to the first piezoelectric motor 7 of the first holding unit 71, a second coupling portion 812 coupling to a motor holding portion 813, the motor holding portion 813 holding the second piezoelectric motor 8 inside, and an attachment portion 814 attaching the gripping unit 9. The first coupling portion 811 extends in directions orthogonal to the first axis O7 of the first piezoelectric motor 7 and couples to the second coupling portion 812, and the second coupling portion 812 extends along the first axis O7 of the first piezoelectric motor 7 from the coupling part to the first coupling portion 811. The second holding unit 81 has the attachment portion 814 that can detachably attach the gripping unit 9 in the distal end portion of the second holding unit. As described above, the gripping unit 9 is detachably provided for the second holding unit 81, and thereby, the gripping unit 9 may be easily replaced according to the details of work. Further, the maintenance of the gripping unit 9 is easier. Note that the attachment method of the attachment portion 814 to the gripping unit 9 is not particularly limited, but may be any method including concavo-convex fitting, screwing, fastening by screws, and magnetic attraction. A gap 66 having a size to prevent contact between the second holding unit 81 and the gripping unit 9 when these units pivot around the first axis O7 is provided between the first coupling portion 711 of the first holding unit 71 and the second coupling portion 812 of the second holding unit 81.

The gripping unit 9 is placed along the second axis O8 of the second piezoelectric motor 8 and coupled pivotably around the second axis O8. The gripping unit 9 has a base portion 91 detachably attached to the attachment portion 814 of the second holding unit 81 and a pair of finger portions 92, 93 sliding in directions orthogonal to the second axis O8. Further, a driver sliding the finger portions 92, 93 is provided within the base portion 91. Note that the gripping unit 9 of the embodiment grips an object with the pair of finger portions 92, 93, however, the configuration is not limited to that. The number of finger portions may be e.g. three or more. Or, a suction portion that suctions an object by negative pressure may be employed.

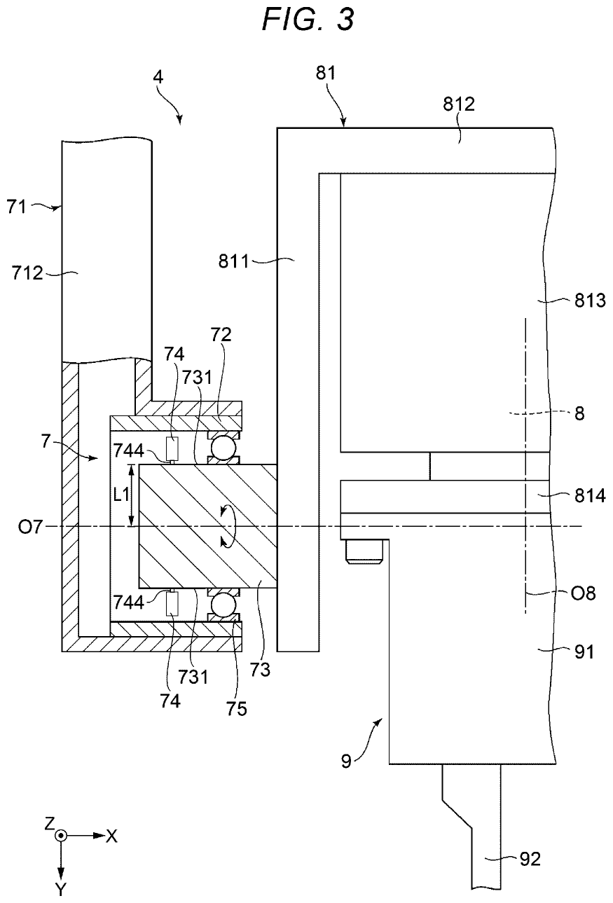

As shown in FIG. 3, the first piezoelectric motor 7 has a housing 72, a rotor 73 rotatable relative to the housing 72, and a plurality of vibrators 74 having convex portions 744 in contact with a contact surface 731 as a side surface of the rotor 73. The housing 72 is fixed to the first holding unit 71. The rotor 73 is supported by the housing 72 via a bearing 75 and rotatable around the first axis O7 relative to the housing 72. The vibrator 74 that transmits a drive force to the rotor 73 as a driven portion is fixed to the housing 72 with the convex portion 744 pressed against the contact surface 731 of the rotor 73 by an urging member (not shown). Note that the plurality of vibrators 74 are placed at a fixed distance L1 from the first axis O7. More specifically, the vibrators are respectively placed at the plus side in the Y direction and the minus side in the Y direction with respect to the first axis O7.

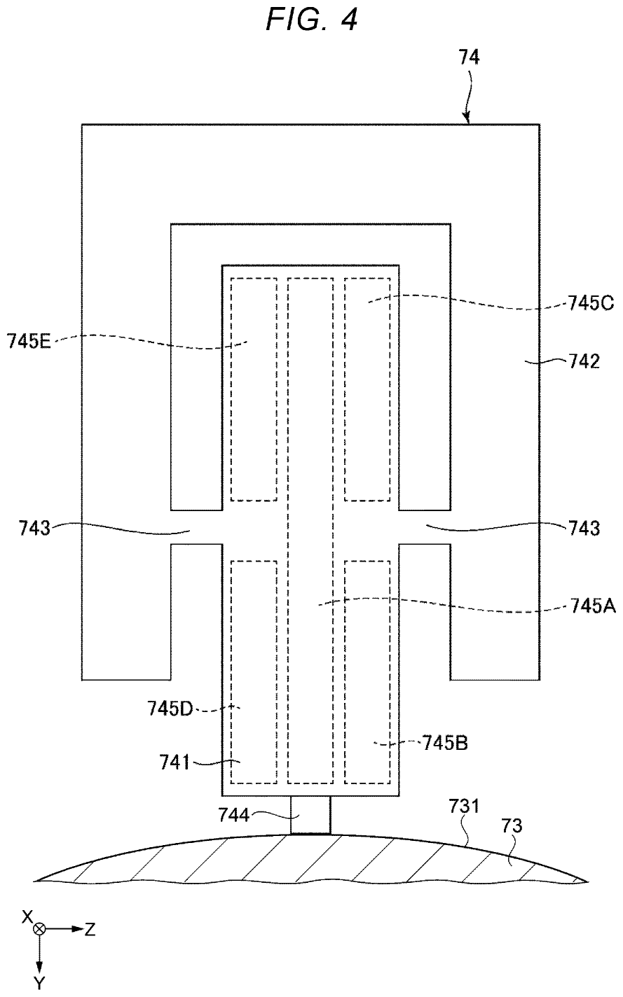

As shown in FIG. 4, the vibrator 74 has a vibrating body 741, a supporting portion 742 supporting the vibrating body 741, a coupling portion 743 coupling the vibrating body 741 and the supporting portion 742, and the convex portion 744 provided on the vibrating body 741 and transmitting vibration of the vibrating body 741 to the rotor 73. In the vibrating body 741, five piezoelectric elements 745A to 745E are placed. These five piezoelectric elements 745A to 745E are each configured to expand and contract in longitudinal directions of the vibrating body 741. When the piezoelectric elements 745A to 745E are expanded and contracted at predetermined timings, the vibrator 74 flexurally vibrates in S shapes and the flexural vibration is transmitted to the rotor 73, and thereby, the rotor 73 rotates around the first axis O7 relative to the housing 72. Accordingly, the first piezoelectric motor 7 may pivot the gripping unit 9 around the first axis O7. Note that the vibrator 74 of the first piezoelectric motor 7 performs flexural vibration as in-plane vibration in the YZ-plane, and the plane containing the vibration surface is orthogonal to the first axis O7 as the rotation axis of the first piezoelectric motor 7. Therefore, the thickness as the length of the first piezoelectric motor 7 in the X directions may be reduced and the width dimension of the end effector 4 along the first axis O7 may be reduced.

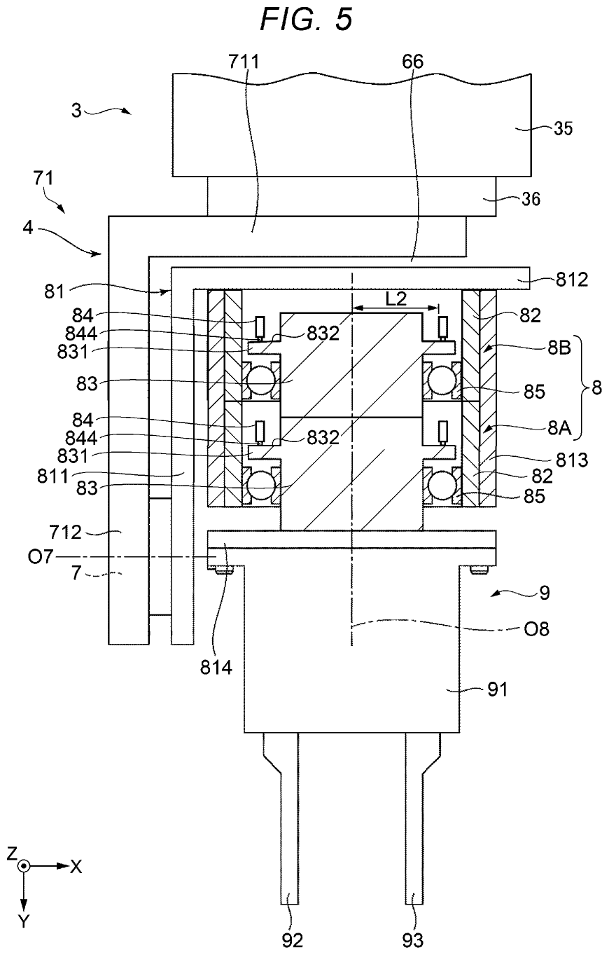

As shown in FIG. 5, the second piezoelectric motor 8 is formed by stacking of two piezoelectric motors 8A, 8B. Each of the two piezoelectric motors 8A, 8B has a plurality of vibrators 84 that transmit drive forces to a rotor 83 as a driven portion. Note that the vibrators 84 have the same configurations as the above described vibrators 74 of the first piezoelectric motor 7.

Each of the two piezoelectric motors 8A, 8B has a housing 82, the rotor 83 rotatable relative to the housing 82, and the plurality of vibrators 84 having convex portions 844 in contact with a contact surface 832 of the rotor 83. The housing 82 is fixed to the second coupling portion 812. The rotor 83 is supported by the housing 82 via a bearing 85 and rotatable around the second axis O8 relative to the housing 82. The rotor 83 has a projecting portion 831 projecting in the outer circumferential direction and the contact surface 832 in contact with the convex portion 844 of the vibrator 84 is provided on the projecting portion 831. The attachment portion 814 is coupled to one portion of the rotor 83 of the piezoelectric motor 8A and the rotor 83 of the piezoelectric motor 8B is coupled to the other portion of the rotor 83 of the piezoelectric motor 8A. The vibrator 84 is fixed to the housing 82 with the convex portion 844 pressed against the contact surface 832 of the rotor 83 by an urging member (not shown).

Note that the plurality of vibrators 84 are placed at a fixed distance L2 from the second axis O8 along the second axis O8 directions as the rotation axis directions of the second piezoelectric motor 8. More specifically, the vibrators are respectively placed at the plus side in the X direction and the minus side in the X direction with respect to the second axis O8. The second piezoelectric motor 8 has lower torque because the distance L2 between the second axis O8 as the rotation axis of the second piezoelectric motor 8 and the vibrator 84 is smaller than the distance L1 between the first axis O7 as the rotation axis of the first piezoelectric motor 7 and the vibrator 74, in other words, the diameter of the rotor 83 of the second piezoelectric motor 8 is smaller than the diameter of the rotor 73 of the first piezoelectric motor 7. Accordingly, to provide equal torque to that of the first piezoelectric motor 7, the second piezoelectric motor 8 is formed using the two piezoelectric motors 8A, 8B. The two piezoelectric motors 8A, 8B having the rotors 83 with the smaller diameters are stacked, and thereby, the width dimension as the length of the second piezoelectric motor 8 in the X directions may be reduced and the width dimension of the end effector 4 along the first axis O7 may be reduced.

When the vibrator 84 is flexurally vibrated in S shapes, the vibration is transmitted to the rotor 83 and the rotor 83 rotates around the second axis O8. Accordingly, the second piezoelectric motor 8 may pivot the gripping unit 9 around the second axis O8 orthogonal to the first axis O7. Note that the vibrator 84 of the second piezoelectric motor 8 performs flexural vibration as in-plane vibration in the YZ-plane, and the plane containing the vibration surface is along the second axis O8 as the rotation axis of the second piezoelectric motor 8.

The first piezoelectric motor 7 of the end effector 4 of the embodiment corresponds to a seventh joint as the second joint from the distal end of the manipulator 3, and the second piezoelectric motor 8 corresponds to an eighth joint at the most distal end of the manipulator 3. Accordingly, the robot 1 of the embodiment is an articulated robot having eight joints.

In the embodiment, the first piezoelectric motor 7 and the second piezoelectric motor 8 are placed in the end effector 4 having the gripping unit 9, however, the first piezoelectric motor 7 may be placed in the fifth arm drive unit 55 near the base 2 and the second piezoelectric motor 8 may be placed in the sixth arm drive unit 56 placed at the distal end side opposite to the base 2. In other words, the piezoelectric motor 7 may be placed in the fifth arm drive unit 55 as the second joint from the distal end of the manipulator 3, and the second piezoelectric motor 8 may be placed in the sixth arm drive unit 56 as the joint at the most distal end. Therefore, the gripping unit 9 is attached to the second piezoelectric motor 8, and thereby, the same function as the end effector 4 may be fulfilled without the end effector 4.

As described above, in the end effector 4 of the robot 1 of the embodiment, the first piezoelectric motor 7 having the rotor 73 with the larger diameter and having the smaller thickness is placed at the base 2 side and the second piezoelectric motor 8 having the rotor 83 with the smaller diameter and having the smaller width dimension is placed at the distal end side opposite to the base 2, and thereby, downsizing of the end effector 4 may be realized. Therefore, the robot 1 easily performing work in a narrow area is obtained.

### 2. Second Embodiment

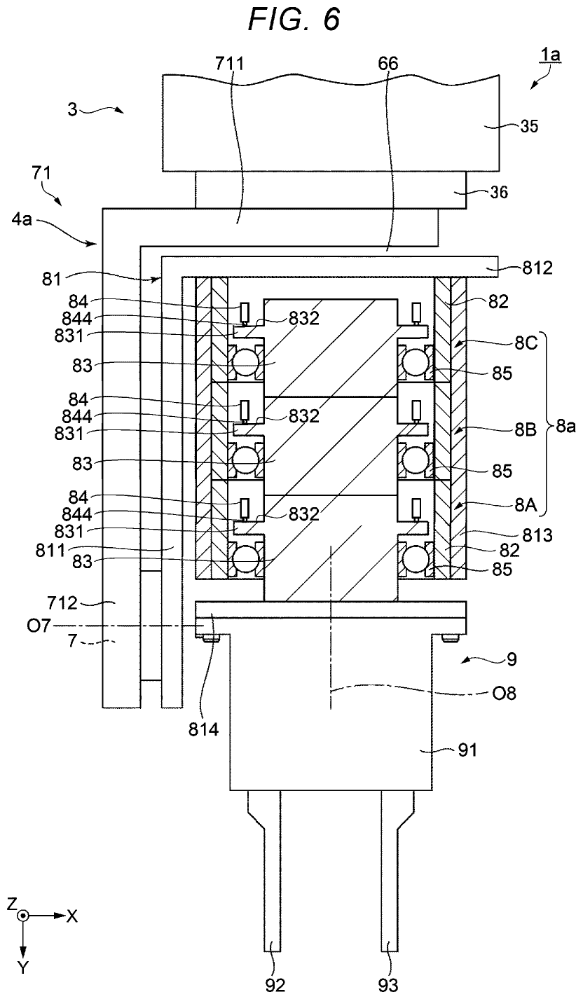

Next, a robot 1a according to a second embodiment will be explained with reference to FIG. 6.

The robot 1a of the embodiment is the same as the robot 1 of the first embodiment except that the configuration of a second piezoelectric motor 8a of an end effector 4a is different. The embodiment will be explained with a focus on the differences from the above described first embodiment and the explanation of the same items will be omitted.

As shown in FIG. 6, the end effector 4a of the robot 1a has the second piezoelectric motor 8a in which three piezoelectric motors 8A, 8B, 8C are stacked.

Each of the three piezoelectric motors 8A, 8B, 8C has the housing 82, the rotor 83 rotatable relative to the housing 82, and the plurality of vibrators 84 having convex portions 844 in contact with the contact surface 832 of the rotor 83. The housing 82 is fixed to the second coupling portion 812. The rotor 83 is supported by the housing 82 via the bearing 85 and rotatable around the second axis O8 relative to the housing 82. The rotor 83 has the projecting portion 831 projecting in the outer circumferential direction and the contact surface 832 in contact with the convex portion 844 of the vibrator 84 is provided on the projecting portion 831. The attachment portion 814 is coupled to one portion of the rotor 83 of the piezoelectric motor 8A, the rotor 83 of the piezoelectric motor 8B is coupled to the other portion of the rotor 83 of the piezoelectric motor 8A, and the rotor 83 of the piezoelectric motor 8C is coupled to the rotor 83 of the piezoelectric motor 8B at the opposite side to the piezoelectric motor 8A. The vibrator 84 is fixed to the housing 82 with the convex portion 844 pressed against the contact surface 832 of the rotor 83 by an urging member (not shown). Note that the plurality of vibrators 84 are respectively placed at the plus side in the X direction and the minus side in the X direction with respect to the second axis O8 along the second axis O8 directions as the rotation axis directions of the second piezoelectric motor 8.

The second piezoelectric motor 8a is formed by stacking of the three piezoelectric motors 8A, 8B, 8C, and thereby, the torque of the second piezoelectric motor 8a may be increased with the width dimension of the end effector 4a along the first axis O7 kept.

According to the configuration, the second piezoelectric motor 8a with the higher torque may be placed and the same effects as those of the robot 1 of the first embodiment may be obtained.

What is claimed is:

1. A robot including a manipulator having a plurality of joints and a base supporting the manipulator, comprising a first piezoelectric motor and a second piezoelectric motor respectively having vibrators that transmit drive forces to a driven portion and performing rotary driving, wherein
a distance between a rotation axis and the vibrator is smaller in the second piezoelectric motor than in the first piezoelectric motor,
a plurality of the vibrators are placed along rotation axis directions in the second piezoelectric motor, and
the second piezoelectric motor is placed closer to a distal end side opposite to the base than the first piezoelectric motor.

2. The robot according to claim 1, wherein
the second piezoelectric motor is placed in a joint at a most distal end, and
the first piezoelectric motor is placed at a second joint from the distal end.

3. The robot according to claim 2, further comprising a gripping unit, wherein
the first piezoelectric motor pivots the gripping unit around a first axis, and
the second piezoelectric motor pivots the gripping unit around a second axis orthogonal to the first axis.

4. The robot according to claim 1, wherein
in the first piezoelectric motor, the vibrator performs in-plane vibration and a plane containing a vibration surface is orthogonal to the rotation axis.

5. The robot according to claim 1, wherein
in the second piezoelectric motor, the vibrator performs in-plane vibration and a plane containing a vibration surface is along the rotation axis.

6. An end effector attached to a distal end of a manipulator, comprising a first piezoelectric motor and a second piezoelectric motor respectively having vibrators that transmit drive forces to a driven portion and performing rotary driving, wherein
a distance between a rotation axis and the vibrator is smaller in the second piezoelectric motor than in the first piezoelectric motor,
a plurality of the vibrators are placed along rotation axis directions in the second piezoelectric motor, and
the second piezoelectric motor is placed closer to a distal end side opposite to the manipulator than the first piezoelectric motor.
